(19) United States
(12) Patent Application Publication
(10) Pub. No.: US 2025/0390459 A1
(43) Pub. Date: Dec. 25, 2025

(54) SERDES MINIATURE PACKAGE AND LAYOUT FOR AUTOMOTIVE AND INDUSTRIAL APPLICATIONS

(71) Applicant: Analog Devices, Inc., Wilmington, MA (US)

(72) Inventors: Mark DIVITO, Wilmington, MA (US); Thomas J. HOUCK, Wilmington, MA (US); Stephen SIMMONS, Wilmington, MA (US); Geir OSTREM, Wilmington, MA (US)

(21) Appl. No.: 19/244,842

(22) Filed: Jun. 20, 2025

Related U.S. Application Data
(60) Provisional application No. 63/663,534, filed on Jun. 24, 2024.

(51) Int. Cl. G06F 13/42; G06F 1/18

(52) U.S. Cl. CPC G06F 13/4282; G06F 1/189

(57) ABSTRACT

An integrated circuit may include a die. An integrated circuit may include a plurality of mixed-signal blocks aligned and coupled with a block grid and having dimensions corresponding to chip dimensions by a common integer factor. An integrated circuit may include a diffusion element having a grid length dimension with a fixed and standardized contact spacing. An integrated circuit may include a power distribution system comprising. An integrated circuit may include one or more tiles with tile dimensions related to the block grid by a common integer factor; and internal tracks configured to provide distribution of a plurality of power supplies in each direction. An integrated circuit may include a set of capacitor elements aligned with the block grid and configured to enable efficient utilization of space between the plurality of mixed-signal blocks.

### CROSS-REFERENCE TO RELATED APPLICATIONS

This application claims the benefit of and priority to U.S. Provisional Application No. 63/663,534, filed Jun. 24, 2024 and titled “SERDES MINIATURE PACKAGE AND LAYOUT FOR AUTOMOTIVE AND INDUSTRIAL APPLICATIONS”, the entire contents of which are hereby incorporated by reference.

### BACKGROUND

### A. Technical Field

Aspects disclosed herein relate to serializer/deserializer (SERDES) circuit, and more specifically to SERDES circuit packaging and layout for automotive and industrial applications.

### B. Background

Gigabit Multimedia Serial Link (GMSL) is a serial link technology that is used for multimedia distribution in various applications, such as In-Vehicle Infotainment (IVI) systems and Advanced driver-assistance systems (ADAS) in vehicles. A serializer/deserializer (SERDES) circuit, e.g., a GMSL serializer, may receive video images from a MIPI Camera Serial Interface 2 (CSI-2) interface and outputs the video images on a GMSL serial link transceiver. Certain GMSL serializers/deserializers may even allow simultaneous transmit bidirectional transmissions over coax cables.

For operation, a serializer needs supporting circuitry, which drives up overall cost and size for circuit packaging. To lower circuity cost and complexity, it is desirable for a serializer to have a smaller footprint and require less supporting circuity to interact with other components, e.g., cameras, Radar/Lidar sensors, etc.

Accordingly, what are needed are systems and methods for minimizing SERDES circuit packaging and layout for automotive and industrial applications.

### SUMMARY

Disclosed herein are systems and methods describing various aspects of SERDES power up operations.

In some aspects, the techniques described herein relate to an integrated circuit including: a die; a plurality of mixed-signal blocks aligned and coupled with a block grid and having dimensions corresponding to chip dimensions by a common integer factor; a diffusion element having a grid length dimension with a fixed and standardized contact spacing; a power distribution system including one or more tiles with tile dimensions related to the block grid by a common integer factor; and internal tracks configured to provide distribution of a plurality of power supplies in each direction; and a set of capacitor elements aligned with the block grid and configured to enable efficient utilization of space between the plurality of mixed-signal blocks.

### BRIEF DESCRIPTION OF THE DRAWINGS

Further details, features and advantages emerge from the following description of preferred aspects with reference to the drawing. Shown are:

FIG. 1 is a block diagram of a deserializer converting multiple serial inputs into MIPI D/C-PHY outputs to a system-on-chip (SoC) according to one or more aspects;

FIG. 2 depicts a typical schematic of a serializer chip with supporting circuity according to one or more aspects;

FIG. 3 depicts a reduction of input/output terminals or pins for a serializer chip according to one or more aspects;

FIG. 4 depicts various grids to enable sharing of boundaries for serializer chip size reduction according to one or more aspects;

FIG. 5 depicts a schematic diagram of boundary/array optimization for serializer chip size reduction according to one or more aspects;

FIG. 6 depicts a schematic diagram of array partitioning for serializer chip size reduction according to one or more aspects;

FIG. 7 depicts a schematic diagram of M1 MOM alignment with MOS Cap for serializer chip size reduction according to one or more aspects;

FIG. 8 depicts a schematic diagram of density interleaving for serializer chip size reduction according to one or more aspects; and

FIG. 9 depicts a schematic diagram of die edge utilization for serializer chip size reduction according to one or more aspects.

### DETAILED DESCRIPTION

In the following description, for the purposes of explanation, specific details are set forth in order to provide an understanding of the aspects. It will be apparent, however, to one skilled in the art that the aspects can be practiced without these details. One skilled in the art will recognize that aspects described below may be performed in a variety of ways and using a variety of means. Those skilled in the art will also recognize additional modifications, applications, and aspects are within the scope thereof, as are additional fields in which the aspects may provide utility. Accordingly, the aspects described below are illustrative of specific aspects.

A reference in the specification to “one aspect” or “an aspect” means that a particular feature, structure, characteristic, or function described in connection with the aspect is included in at least one aspect. The appearance of the phrase “in one aspect,” “in an aspect,” or the like in various places in the specification are not necessarily all referring to the same aspect.

Connections illustrated in the figures between components may be modified or otherwise changed through the addition thereto of intermediary components, without departing from the teachings herein.

Furthermore, one skilled in the art shall recognize: (1) that certain steps may optionally be performed; (2) that steps may not be limited to the specific order set forth herein; and (3) that certain steps may be performed in different orders, including being done contemporaneously.

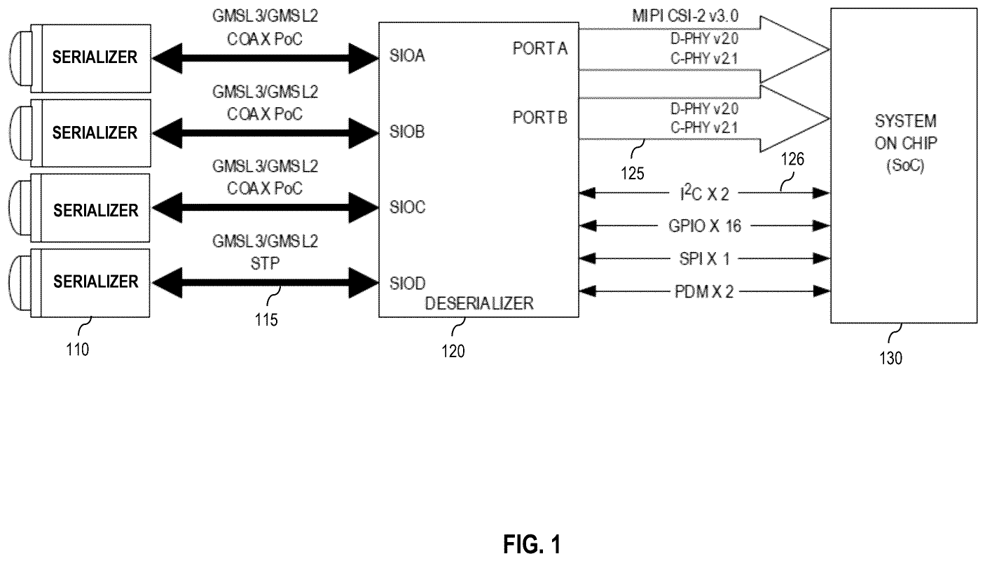

FIG. 1 is a block diagram of a deserializer converting multiple serial inputs into MIPI D/C-PHY outputs to a system-on-chip (SoC) according to one or more aspects. The deserializer 120 comprises multiple serial I/O ports, e.g., SIOA˜SIOD, to communicate with multiple serializers 110 via respective serial links 115. The deserializer 120 also comprises one or more interfaces, e.g., PORT A and PORT B, to communicate ports, e.g., SIOA˜SIOD, to communicate with an integrated circuit 130, e.g., a system-on-chip (SoC), via respective serial channels 125.

The serializers 110 may be camera modules that are used to capture video images. The serial links 115 may be GMSL links on a power over coaxial (PoC) cable or a shielded twisted-pair (STP) cable that supports high data rate of transmission over a single cable. The serial channels 125 may use different protocols from the serial links 115 for communication between the deserializer 120 and the integrated circuit 130. In one or more aspects, the serial channels 125 may use Mobile Industry Processor Interface (MIPI) Camera Serial Interface 2 (CSI-2) protocol, a high-speed protocol for transmission of still and video images from image sensor(s) to processors. The MIPI defines a set of physical layers including C-PHY and D-PHY for camera, display and chip to chip communication. As shown in FIG. 1, the deserializer 120 converts multiple serial inputs in a first protocol (e.g., GMSL2, GMSL3, or a mixed GMSL2/3) from the multiple serializers 110 into one or more serial outputs in a second protocol, e.g., MIPI D/C-PHY.

Besides the serial channels 125, the deserializer 120 may communicate with the integrated circuit 130 via other interfaces, such as one or more I2C interface ports 126, serial peripheral interface (SPI) connection, and/or general purpose input/output (GPIO) connections, etc.

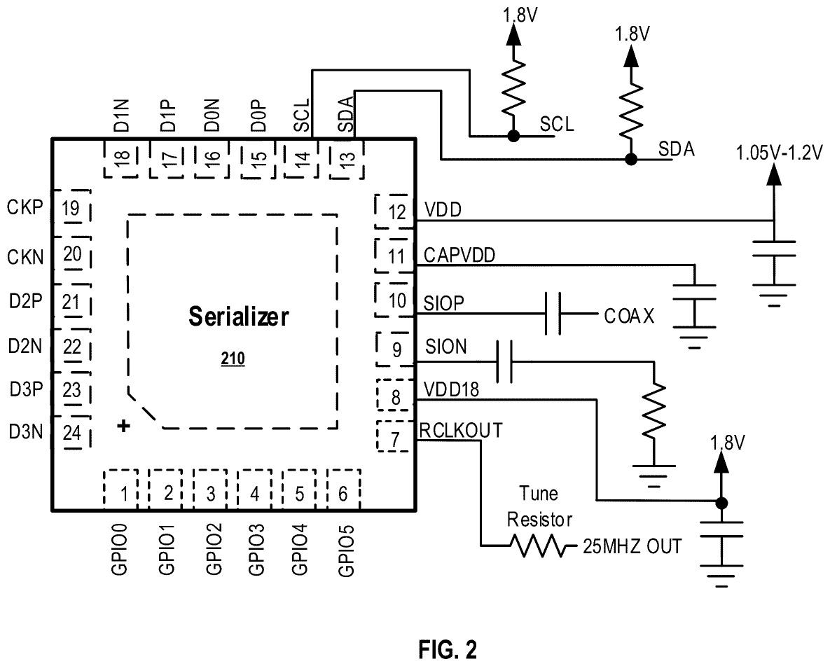

FIG. 2 depicts a typical schematic of a serializer chip with supporting circuity according to one or more aspects. The serializer 210 comprises multiple I/O terminals or pins for serial data I/O, multiple data lanes (e.g., D0˜D3), and I2C serial data I/O (SDA). Each data lane comprises a non-inverted input pin (e.g., D0P, D1P, etc.) and an inverted input pin (e.g., D0N, D1N, etc.). Pins for serial data I/O comprise a non-inverted serial-data I/O pin (SIOP) and an inverted serial-data I/O pin (SION). The serializer 200 further comprises pins for a clock lane (CK) which has a non-inverted clock input PIN (CKP) and an inverted clock input PIN (CKN), multiple configurable pins (e.g., GPIO0˜GPIO5) for general-purpose input/output (GPIO), and an I2C serial clock pin (SCL).

Besides, the serializer 210 may comprise a plurality of pins for other purposes, such as a reference clock output pin (RCLKOUT) for providing a reference clock (e.g., 25 MHz clock) to a sensor, a voltage input pin (VDD18) for connection to an external 1.8V power supply, a digital core supply pin (VDD pin) for connection to a digital core supply of 1.05V-1.2V, a ground pin (EP) for ground connection, and a decoupling capacitor (CAP_VDD) pin for connection to a decoupling Capacitor for the VDD core supply.

To lower circuity cost and complexity, it is desirable for a serializer to have a smaller footprint and require less supporting circuity to interact with other components, e.g., cameras, Radar/Lidar sensors, etc. To achieve a small form factor for a serializer integrated circuit (IC), pin count may need to be reduced maintaining Automotive Safety Integrity Level (ASIL) compliance. In one or more aspects, the serializer IC is designed with multiple related grid approach and effective edge utilization to make the IC die compact, thus allowing usage of downbonds within the IC package. Furthermore, roughened lead frame may be utilized to allow the IC die to attach reliably to the lead frame despite the small footprint.

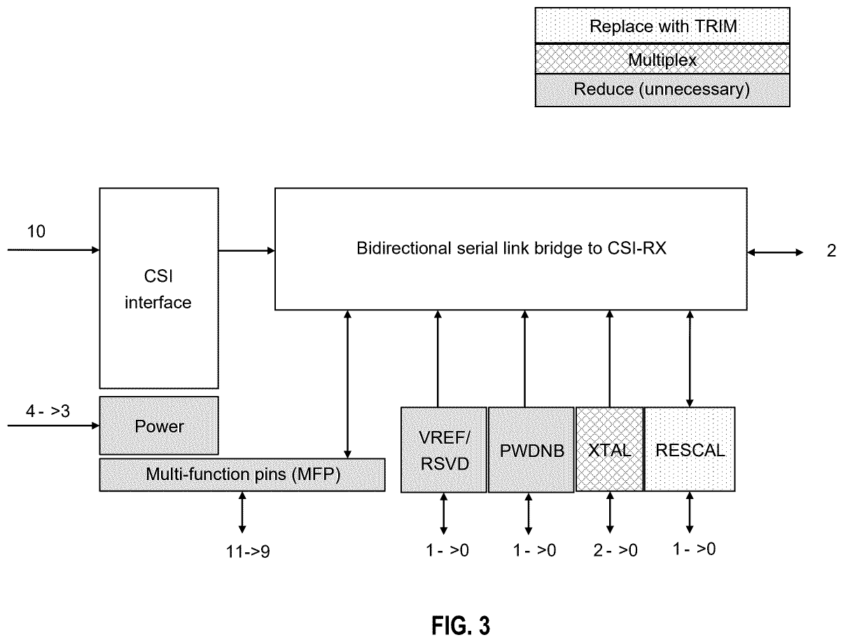

FIG. 3 depicts a reduction of input/output terminals or pins for a serializer chip according to one or more aspects. Using one or more aspects chip layout optimization methodologies described hereinafter in details, a serializer chip may be improved in reduction of footprint and pin numbers. As shown in FIG. 3, the shaded or pattern filled section of the serializer chip may have pin numbers reduced or even removed. For example, pins for reserved reference voltage (VREF/RSVD), power-down mode (PWDNB), external oscillator (XTAL) in a traditional serializer chip may be eliminated, while pins for power may be reduced from four in a traditional serializer chip to three (e.g., the VDD, VDD18, and CAPVDD pins shown in FIG. 2). The serializer chip may be smaller in chip size, have fewer pins, and require a supporting circuity of less complexity. Therefore, the overall size and cost for system implementation may be lowered. In various aspects, XTAL and diagnostic functions with GPIOs can be multiplexed. In various aspects a quantity of power pins can be reduced. In various aspects calibration and reference pins can be replaced via trimming ATE.

Typically, an integrated circuit (IC) comprises many different independent elements and arrays of elements of various sizes. Fitting different sized elements together leads to numerous gaps, which cause chip space waste. In one or more aspects, a system of grids is used to enable sharing of boundaries with flexibility in sizing and arbitrary arrangement within the chip. The sharing of boundaries may involve block development that involves one or more innovations of capacitor element design, resistor array design, utilizing capacitor as boundary fill, device interleaving, etc.

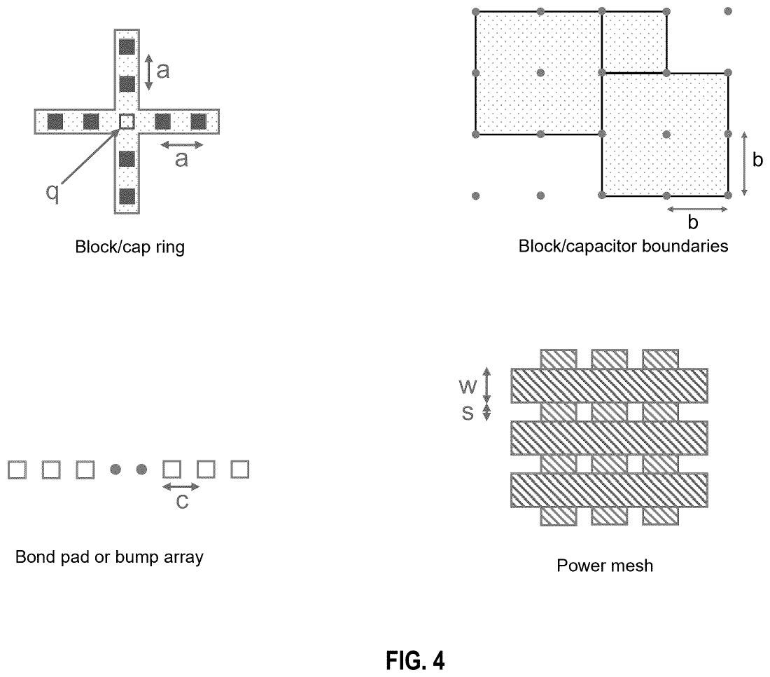

FIG. 4 depicts various grids (also referred to herein as block grids) to enable sharing of boundaries for serializer chip size reduction according to one or more aspects. In FIG. 4, “a” represents the pitch of vias/contacts, “b” represents a dimension unit for blocks (also referred to herein as mixed-signal blocks) or capacitors which use sizes having integer multiples of such a dimension unit, “c” represents the pitch of bond pad or bump pitch, and “w” and “s” respectively represent width and space of a power mesh that alternate between N nets comprising at least one net as voltage source supply (VSS), at least one net as voltage drain (VDD), and at least one net as a variable supply. In some aspects, the power mesh is a power distribution system. In various aspects, internal tracks can be configured to provide distribution of power supplies in each direction. In some aspects, one or more tiles are included, having tile dimensions.

In one or more aspects, the a, b, and c are designated to meet the requirements of b=K×a; c=M×b; c=L×N×(w+s); (w+m)/(w+s)=d, wherein K, L, M, and N are integers, m is manufacturing grid, a is the contact pitch, and d is the maximum metal density, which is a ratio representing the percentage of the metal mask that contains metal in the context of IC design. In other words, c is a multiple of b and also a multiple of the sum of w and s, while b is a multiple of a. In other words, one or more tiles have dimensions related to the block grid by a common integer factor. Such arrangements ensure the blocks and components in the serializer chip may share boundaries for reduced chip size and packaging. Furthermore, every K-th boundary contact/via is removed (e.g., at a vertex) to solve the 3-neighbor problem. Contacts with more than two neighbors need to use wider spacing. When two lines (e.g., straight lines) of contacts meet perpendicularly, the contact at the vertex of the two lines will have a neighbor above and below as well as one to each side. Therefore, the contact would need wider spacing. Such a wider spacing requirement is referred to as a 3-neighbor problem. One solution is to omit the central contact, and this enables the overall pitch to align with the other grids in the system. That is, there may be a plurality of contacts between the diffusion element and edges of the one or more mixed signal blocks enabling arbitrary sharing on grid boundaries, but contacts are omitted at grid vertices. In various aspects, contact spacing can be fixed and/or standardized.

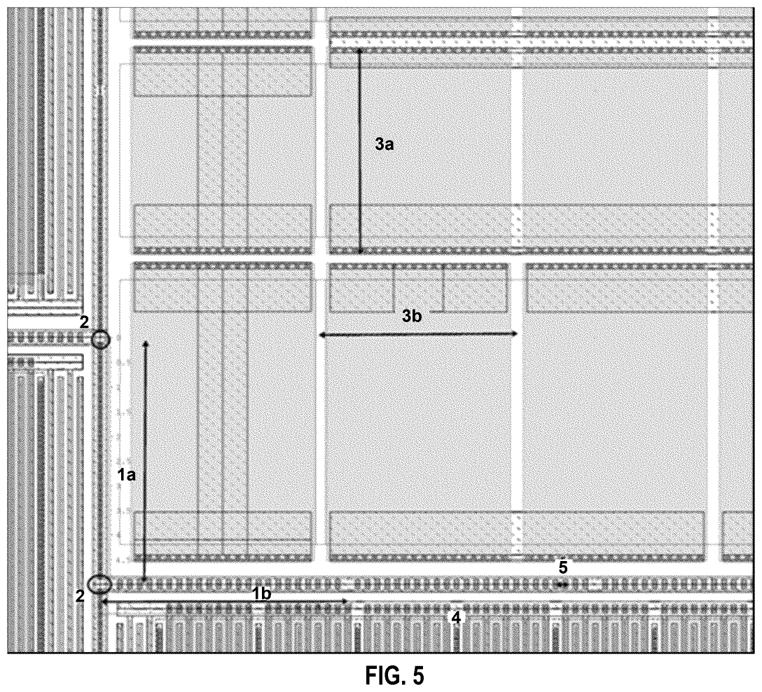

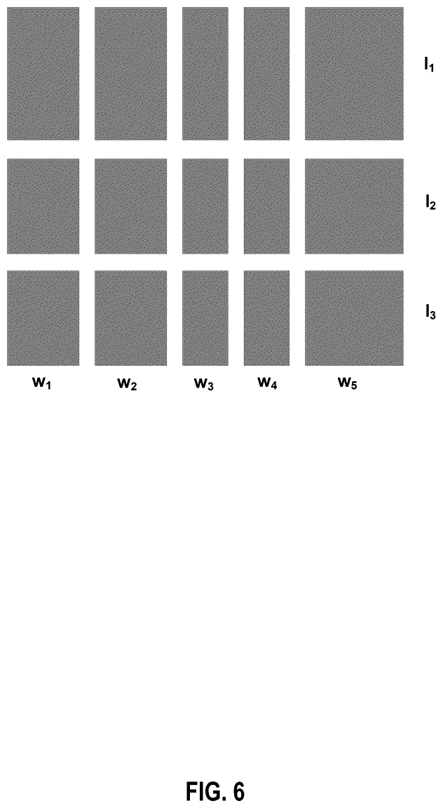

Typically, various circuit functions require non-uniform combination of resistors, and thus leading to varying widths and lengths for resistors. Putting resistors of different lengths on the same row requires wider spacing between resistors and leaves gaps within the row, which causes wasted space. In one or more aspects, resistors are aligned in length by rows and in width by columns, as shown in 3a and 3b in FIG. 5. A set of resistors is partitioned into multiple series-parallel combinations using a minimum set of lengths and widths. Resistors of a common length (e.g., I₁, I₂, or I₃, as shown in FIG. 6) are aligned on the same row and resistors of a common width are aligned in the same column. Rows and columns are then sorted to minimize interconnection distances. In one or more aspects, a scale matrix may be used for resistors by one or more factors to meet random such that grid boundary may be quantized. The resistor matrix may be scaled such that the height and width both are quantized by K×a to minimize Monte Carlo variation without wasting space.

FIG. 6 depicts a schematic diagram of array partitioning for serializer chip size reduction according to one or more aspects. As shown in FIG. 6, with proper row/column alignment, spacing between resistors may be uniform for minimized space waste.

In an integrated circuit, metal lines at level 1 (M1) is used for transistor source, drain, and gate connections on metal-oxide-semiconductor (MOS) capacitors and is used to implement the fringing capacitance of a first layer of metal-oxide-metal (MOM) capacitors. Fringing capacitance is additional capacitance beyond an “expected” capacitance under uniform field (V/d) between the electrodes and zero field elsewhere. Fringing capacitance is caused by non-uniform field appearing near edge of electrodes.

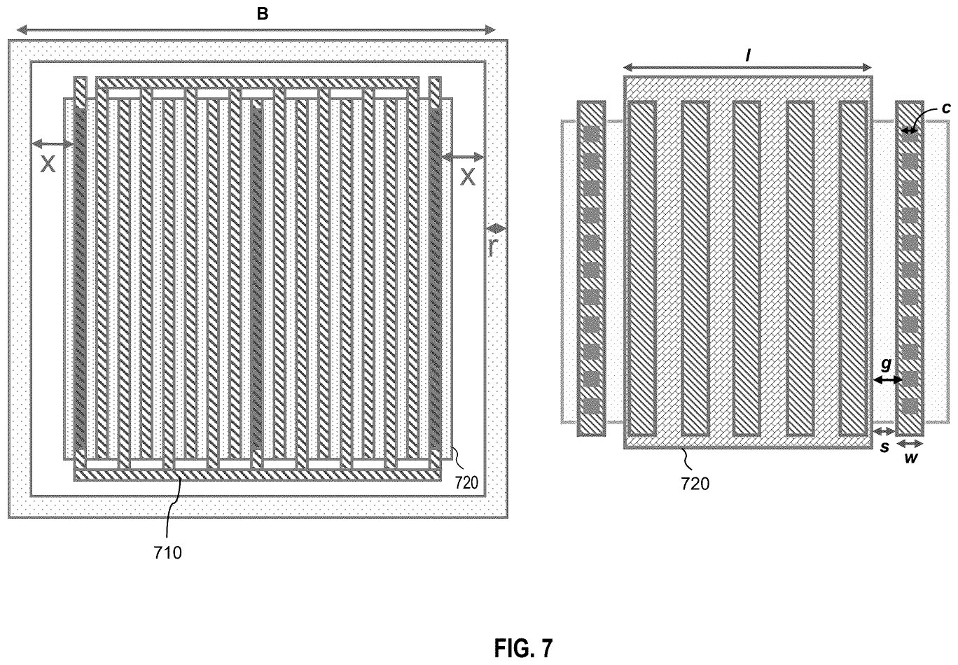

In one or more aspects MOS and MOM capacitors are overlaid in alignment to share the same space. Such an alignment may involve aligning source/drain connection of MOS devices with the M1 finger pitch of one or more fingers (e.g., multi-fingers). FIG. 7 depicts a schematic diagram of M1 finger pitch 710 alignment with MOS capacitor 720 for serializer chip size reduction according to one or more aspects. An MOS capacitor gate length L is chosen as L=2N×(w+s)−2g−2e, where w=minimum M1 width, s=minimum M1 space, g=gate-to-contact space, e=M1 extension on contact, and N is an integer. The sum of capacitor gate lengths for a capacitor array may be adjusted such that the capacitor array uses a maximum width available within a substrate ring. The width of the capacitor array may also be adjusted to meet maximum diffusion and poly density limits.

In one or more aspects, finger lengths of the M1 finger pitch 710 need to be from a set of valid lengths defined by MOM-MOS interaction. The sum of M lengths may be given by B=Σ^{l}ᵢ+2x+M×(2c+2g)+r, wherein B is marked in FIG. 7 as the distance from the center of the rectangle (that makes up the ring formed from a plurality of straight lines) to center of the rectangle, x is the separation from ring diffusion to contact on transistor, c is the contact size, g is the gate-to-contact space, and r is the width of the ring diffusion, as shown in FIG. 7. The finger width W in FIG. 7 is given by W=(B²×d−2rB+2r²)/(Σ^{l}ᵢ+M×(2c+2g+q), wherein q is the extension of diffusion beyond contacts in source-drain direction. It shall be noted that “B” in FIG. 7 should be an integer multiple of “b” in FIG. 4, and the integer multiple used in the X and Y directions can be different. Accordingly, the equations reference only square configurations, not rectangular.

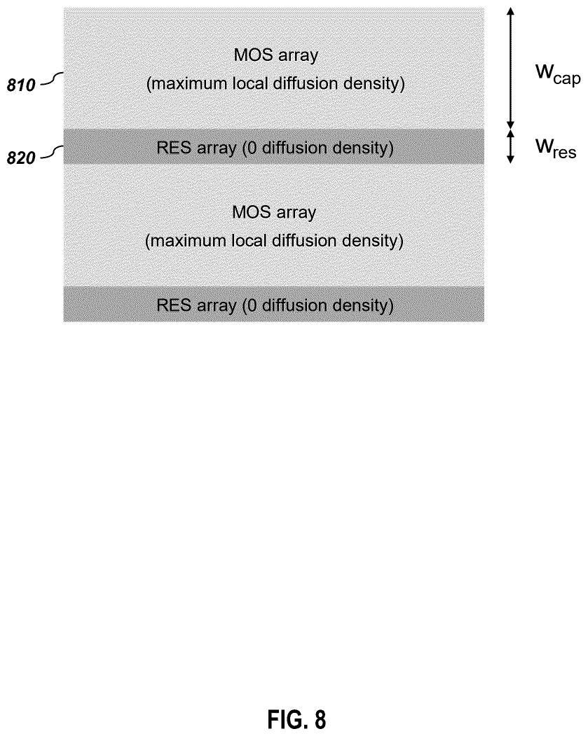

In a typical integrated circuit large cap and switch arrays are limited by maximum diffusion density and large resistor arrays are limited by minimum diffusion density, which brings challenges for chip size reduction. In one or more aspects, MOS arrays and resistor arrays are interleaved for serializer chip size reduction, as shown in FIG. 8. MOS arrays 810 and resistor arrays 820 are alternated within the diffusion window size. The MOS arrays may have maximum local diffusion density, while the resistor arrays have zero diffusion density. Such arrangement may enable effective increase of density of MOS arrays of 10% and avoid adding space to resistor arrays for dummy diffusion. The array interleaving may require careful planning since MOS and resistor arrays may not always be in the same hierarchical blocks.

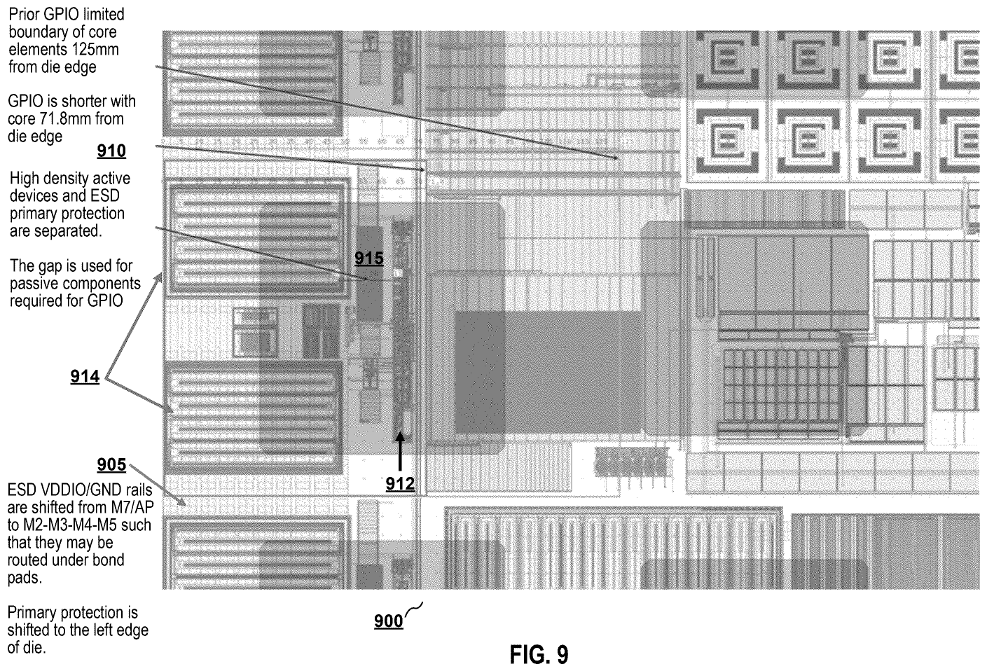

Traditionally, the usage of thick-metal for electrostatic discharge (ESD) supply and ground rails prevents rails from sharing space with pads and thus prevents the core from utilizing space under pads. Such an implementation wastes about 50 μm of die in both X and Y die dimensions. FIG. 9 depicts a schematic diagram of die edge utilization for serializer chip size reduction according to one or more aspects. As shown in FIG. 9, wider stacked thin-metal under pads are utilized with ESD supply and a driver cell implemented in a single signal layer to allow the driver to shift to the edge of the die. Furthermore, primary IO circuits and protection are moved to the left edge of the die 900. Gaps between the ESD circuits and high density logic may be filled with passive devices for higher utilization of space, thus further enabling a compact packaging size.

As shown in FIG. 9, ESD VDDIO/GND rails 905 are shifted from metal lines at level 7 (M7) to lower levels (e.g., M2-M3-M4-M5) such that the rails may be routed under bond pads. As shown in FIG. 9, rails 905 point to the bottom left corner of the group of multiple vertical rails (e.g., 10) in the figure. As a result, primary protection is disposed to edges of the die. GPIO becomes shorter with core 910 closer (e.g., 70 μm) to die edge, compared to 125 μm distance of core elements to die edge due to GPIO limited boundary. Furthermore, high density active devices (e.g., transistors, transmitters, etc.) 912 and ESD primary protection circuits 914 are separated with the gap 915 used for passive components (e.g., resistors, capacitors, etc.) required for GPIO.

Some further example aspects of the integrated circuits described herein are provided in the following clauses.

Clause 1. An integrated circuit comprising: a die; a plurality of mixed-signal blocks aligned and coupled with a block grid and having dimensions corresponding to chip dimensions by a common integer factor; a diffusion element having a grid length dimension with a fixed and standardized contact spacing; a power distribution system comprising one or more tiles with tile dimensions related to the block grid by a common integer factor; and internal tracks configured to provide distribution of a plurality of power supplies in each direction; and a set of capacitor elements aligned with the block grid and configured to enable efficient utilization of space between the plurality of mixed-signal blocks.

Clause 2. The integrated circuit of clause 1, wherein the diffusion element is a ring comprising: a plurality of straight lines.

Clause 3. The integrated circuit of clause 1 or clause 2, wherein the diffusion element further comprises: a plurality of contacts between the diffusion element and edges of the one or more mixed signal blocks enabling arbitrary sharing on grid boundaries, wherein contacts are omitted at grid vertices.

Clause 4. The integrated circuit of any of the above clauses, wherein the set of capacitor elements comprises a capacitor array.

Clause 5. The integrated circuit of clause 4, wherein the set of capacitor elements include a plurality of capacitor element sizes.

Clause 6. The integrated circuit of clause 5, wherein the capacitor array further comprises: a plurality of multi-finger metal-oxide-metal (MOM) capacitor layers within a shared boundary having spaces between the layers.

Clause 7. The integrated circuit of clause 6, wherein the capacitor array further comprises: a set of multi-finger metal-oxide-semiconductor (MOS) capacitor devices whose source, drain, and boundaries align with MOM capacitor metal fingers

Clause 8. The integrated circuit of clause 7, wherein the MOS capacitor devices are aligned and overlayed with the MOM capacitor devices.

Clause 9. The integrated circuit of any of the above clauses, further comprising a serializer with a reduced pin counts, such that: XTAL and diagnostic functions with GPIOs are multiplexed; a quantity of power pins is reduced; and calibration and reference pins are replaced via trimming ATE.

Clause 10. The integrated circuit of any of the above clauses, further comprising: one or more electrostatic discharge (ESD) protection circuits, comprising: a power supply (VDD); and ground with rails routed under bond pads and configured such that ESD circuitry is disposed at an edge of the die.

Clause 11. The integrated circuit of any of the above clauses, wherein the plurality of mixed-signal blocks comprises: one or more metal-oxide-semiconductor (MOS) arrays; and one or more resistor arrays, wherein the one or more MOS arrays and one or more resistor arrays are interleaved.

Clause 12. The integrated circuit of clause 11, wherein, for each resistor array, resistors of a common length are aligned on a same row and resistors of a common width are aligned on a same column.

Clause 13. The integrated circuit of clause 12, wherein the resistor array comprises uniform spacing between rows and between columns.

It shall be noted that all though the above disclosure are described in the context of a serializer circuit, one of more aspects may be applicable to other integrated circuits, separately or in combination, to achieve a smaller footprint for chip packaging.

Aspects of the present disclosure may be encoded upon one or more non-transitory computer-readable media with instructions for one or more processors or processing units to cause steps to be performed. It shall be noted that the one or more non-transitory computer-readable media shall include volatile and non-volatile memory. It shall be noted that alternative implementations are possible, including a hardware implementation or a software/hardware implementation. Hardware-implemented functions may be realized using ASIC(s), programmable arrays, digital signal processing circuitry, or the like. Accordingly, the “means” terms in any claims are intended to cover both software and hardware implementations. Similarly, the term “computer-readable medium or media” as used herein includes software and/or hardware having a program of instructions embodied thereon, or a combination thereof. With these implementation alternatives in mind, it is to be understood that the figures and accompanying description provide the functional information one skilled in the art would require to write program code (i.e., software) and/or to fabricate circuits (i.e., hardware) to perform the processing required.

It shall be noted that aspects of the present disclosure may further relate to computer products with a non-transitory, tangible computer-readable medium that have computer code thereon for performing various computer-implemented operations. The media and computer code may be those specially designed and constructed for the purposes of the present disclosure, or they may be of the kind known or available to those having skill in the relevant arts. Examples of tangible computer-readable media include, but are not limited to: magnetic media such as hard disks, floppy disks, and magnetic tape; optical media such as CD-ROMs and holographic devices; magneto-optical media; and hardware devices that are specially configured to store or to store and execute program code, such as application specific integrated circuits (ASICs), programmable logic devices (PLDs), flash memory devices, and ROM and RAM devices. Examples of computer code include machine code, such as produced by a compiler, and files containing higher level code that are executed by a computer using an interpreter. Aspects of the present disclosure may be implemented in whole or in part as machine-executable instructions that may be in program modules that are executed by a processing device. Examples of program modules include libraries, programs, routines, objects, components, and data structures. In distributed computing environments, program modules may be physically located in settings that are local, remote, or both.

One skilled in the art will recognize no computing system or programming language is critical to the practice of the present disclosure. One skilled in the art will also recognize that a number of the elements described above may be physically and/or functionally separated into sub-modules or combined together.

It will be appreciated to those skilled in the art that the preceding examples and aspects are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure.

What is claimed is:

1. An integrated circuit comprising:
a die;
a plurality of mixed-signal blocks aligned and coupled with a block grid and having dimensions corresponding to chip dimensions by a common integer factor;
a diffusion element having a grid length dimension with a fixed and standardized contact spacing;
a power distribution system comprising:
one or more tiles with tile dimensions related to the block grid by a common integer factor; and
internal tracks configured to provide distribution of a plurality of power supplies in each direction; and
a set of capacitor elements aligned with the block grid and configured to enable efficient utilization of space between the plurality of mixed-signal blocks.

2. The integrated circuit of claim 1, wherein the diffusion element is a ring comprising:
a plurality of straight lines.

3. The integrated circuit of claim 1, wherein the diffusion element further comprises:
a plurality of contacts between the diffusion element and edges of the plurality of mixed-signal blocks enabling arbitrary sharing on grid boundaries, wherein contacts are omitted at grid vertices.

4. The integrated circuit of claim 1, wherein the set of capacitor elements comprises a capacitor array.

5. The integrated circuit of claim 4, wherein the set of capacitor elements include a plurality of capacitor element sizes.

6. The integrated circuit of claim 5, wherein the capacitor array further comprises:
a plurality of multi-finger metal-oxide-metal (MOM) capacitor layers within a shared boundary having spaces between the layers.

7. The integrated circuit of claim 6, wherein the capacitor array further comprises:
a set of multi-finger metal-oxide-semiconductor (MOS) capacitor devices whose source, drain, and boundaries align with MOM capacitor metal fingers.

8. The integrated circuit of claim 7, wherein the MOS capacitor devices are aligned and overlayed with the MOM capacitor devices.

9. The integrated circuit of claim 7, further comprising a serializer with a reduced pin count, such that:
XTAL and diagnostic functions with GPIOs are multiplexed;
a quantity of power pins is reduced; and
calibration and reference pins are replaced via trimming ATE.

10. The integrated circuit of claim 1, further comprising:
one or more electrostatic discharge (ESD) protection circuits, comprising:
a power supply (VDD); and
ground with rails routed under bond pads and configured such that ESD circuitry is disposed at an edge of the die.

11. The integrated circuit of claim 1, wherein the plurality of mixed-signal blocks comprises:
one or more metal-oxide-semiconductor (MOS) arrays; and
one or more resistor arrays,
wherein the one or more MOS arrays and one or more resistor arrays are interleaved.

12. The integrated circuit of claim 11, wherein, for each resistor array, resistors of a common length are aligned on a same row and resistors of a common width are aligned on a same column.

13. The integrated circuit of claim 12, wherein the resistor array comprises uniform spacing between rows and between columns.
